(19) United States
(12) Patent Application Publication
(10) Pub. No.: US 2018/0339901 A1
(43) Pub. Date: Nov. 29, 2018

(54) SEMICONDUCTOR PROCESS

(71) Applicant: United Microelectronics Corp., Hsinchu (TW)

(72) Inventors: Guo-Chih Wei, Taichung City (TW); Weng-Yi Chen, Hsinchu County (TW); Shih-Wei Li, Taoyuan City (TW)

(73) Assignee: United Microelectronics Corp., Hsinchu (TW)

(21) Appl. No.: 15/644,430

(22) Filed: Jul. 7, 2017

(30) Foreign Application Priority Data
May 25, 2017 (CN) 201710377577.8

(51) Int. Cl. B81C 1/00

(52) U.S. Cl. CPC B81C 1/00801; B81C 2201/053; B81B 2201/0207; B81B 2201/0257; B81B 2201/0214; B81B 2201/0235

(57) ABSTRACT

A semiconductor process including the following steps is provided. A wafer is provided. The wafer has a front side and a back side. The wafer has a semiconductor device on the front side. A protection layer is formed on the front side of the wafer. The protection layer covers the semiconductor device. A material of the protection layer includes a photoresist material. A surface hardening treatment process is performed on the protection layer. A first patterning process is performed on the back side of the wafer. The semiconductor process can effectively protect the front side of the wafer during a backside process.

### CROSS REFERENCE TO RELATED APPLICATION

This application claims the priority benefits of China application serial no. 201710377577.8, filed on May 25, 2017. The entirety of the above-mentioned patent application is hereby incorporated by reference herein and made a part of specification.

### BACKGROUND OF THE INVENTION

### Field of the Invention

The invention relates to a semiconductor process, and more particularly to a semiconductor process that protects a front side of a wafer during a backside process.

### Description of Related Art

Currently, when performing a patterning process on a back side of a wafer to form an opening (such as a cavity or a through hole), the industry often uses a photoresist material as a protection layer for protecting a front side of the wafer. However, if the photoresist material provides insufficient protection, damage may still occur in a semiconductor device on the front side of the wafer.

Accordingly, the industry has proposed a solution in which PIQ (a polyimide resin produced by Hitachi Chemical co., ltd.) is used as the protection layer for the front side of the wafer. While the PIQ resin provides better protection during a dry etching process, it is likely to peel off during a wet etching process and thus fails to provide protection.

### SUMMARY OF THE INVENTION

The invention proposes a semiconductor process that effectively protects a front side of a wafer during a backside process.

The invention provides a semiconductor process including the following steps. A wafer is provided, wherein the wafer has a front side and a back side, and the wafer has a semiconductor device on the front side. A protection layer is formed on the front side of the wafer, wherein the protection layer covers the semiconductor device, and a material of the protection layer includes a photoresist material. A surface hardening treatment process is performed on the protection layer. A first patterning process is performed on the back side of the wafer.

According to an embodiment of the invention, in the semiconductor process, the semiconductor device is, for example, a microelectromechanical system (MEMS) device or a logic device.

According to an embodiment of the invention, in the semiconductor process, the MEMS device is, for example, a sensor device.

According to an embodiment of the invention, in the semiconductor process, the sensor device is, for example, an accelerometer, a MEMS microphone, a photosensor or a gas sensor.

According to an embodiment of the invention, the semiconductor process further includes, before or after forming the protection layer, performing a thinning process on the back side of the wafer.

According to an embodiment of the invention, in the semiconductor process, the thinning process is, for example, a grinding process.

According to an embodiment of the invention, in the semiconductor process, the photoresist material is, for example, an I-line photoresist, an ArF photoresist or a KrF photoresist.

According to an embodiment of the invention, the semiconductor process further includes, before performing the surface hardening treatment process, performing a second patterning process on the protection layer.

According to an embodiment of the invention, in the semiconductor process, the second patterning process is, for example, a lithography process.

According to an embodiment of the invention, in the semiconductor process, the surface hardening treatment process includes performing an ion implantation process, an UV treatment or an e-beam treatment on the protection layer.

According to an embodiment of the invention, in the semiconductor process, a dopant of the ion implantation process is, for example, phosphorus, boron or arsenic.

According to an embodiment of the invention, in the semiconductor process, an implantation concentration of the ion implantation process is, for example, 1×10¹⁵ ions/cm² to 4×10¹⁵ ions/cm².

According to an embodiment of the invention, in the semiconductor process, an implantation energy of the ion implantation process is, for example, 50 keV to 100 keV.

According to an embodiment of the invention, the semiconductor process further includes, before performing the ion implantation process, performing an anneal process on the protection layer.

According to an embodiment of the invention, in the semiconductor process, a temperature of the anneal process is, for example, 150° C. to 250° C.

According to an embodiment of the invention, in the semiconductor process, the first patterning process includes the following steps. A patterned photoresist layer is formed on the back side of the wafer. A portion of the wafer is removed from the back side of the wafer using the patterned photoresist layer as a mask.

According to an embodiment of the invention, in the semiconductor process, a method for removing the portion of the wafer is, for example, a dry etching process, a wet etching process or a combination thereof.

According to an embodiment of the invention, in the semiconductor process, the dry etching process is, for example, a deep reactive ion etching (DRIE) process.

According to an embodiment of the invention, the semiconductor process further includes, after removing the portion of the wafer, removing the patterned photoresist layer.

According to an embodiment of the invention, the semiconductor process further includes, after performing the first patterning process, removing the protection layer.

Based on the above, in the semiconductor process proposed by the invention, since the protection layer is subjected to the surface hardening treatment process, when the patterning process is performed on the back side of the wafer, the surface hardening-treated protection layer can effectively protect the front side of the wafer. Thus, the semiconductor device on the front side of the wafer can be prevented from being damaged, and reliability and yield of the semiconductor device can be further improved.

To make the above features and advantages of the invention more comprehensible, embodiments accompanied with drawings are described in detail as follows.

### BRIEF DESCRIPTION OF THE DRAWINGS

FIG. 1 is a flowchart of a semiconductor process according to an embodiment of the invention.

FIG. 2A to FIG. 2G are cross-sectional views of the semiconductor process according to an embodiment of the invention.

### DETAILED DESCRIPTION OF DISCLOSED EMBODIMENTS

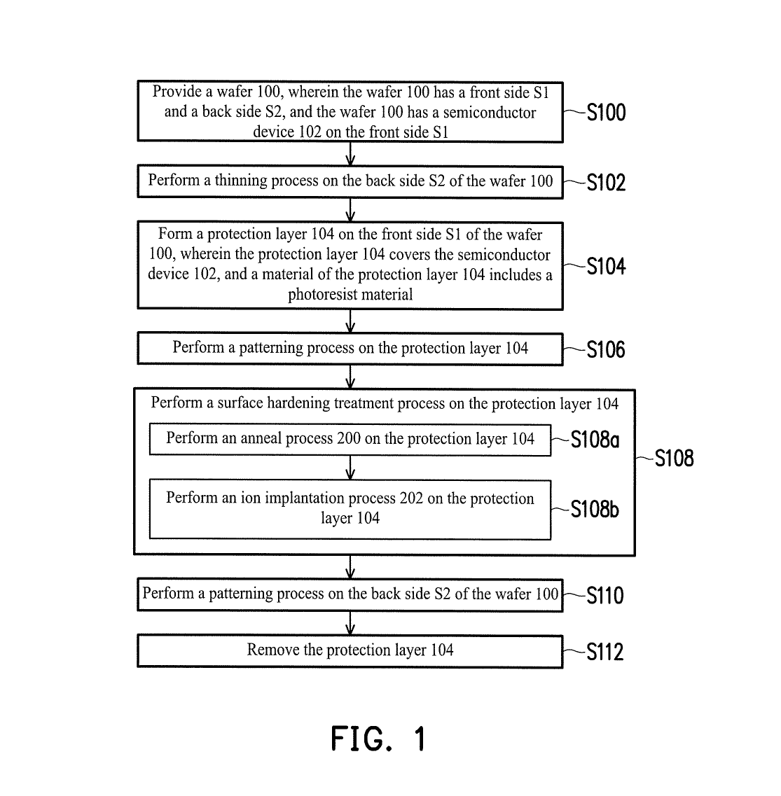

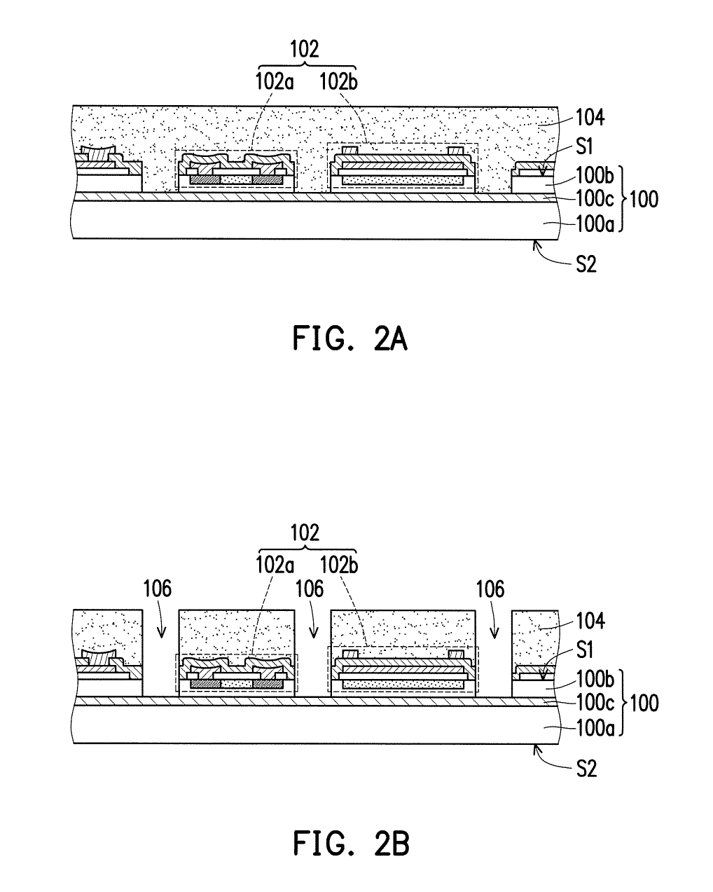

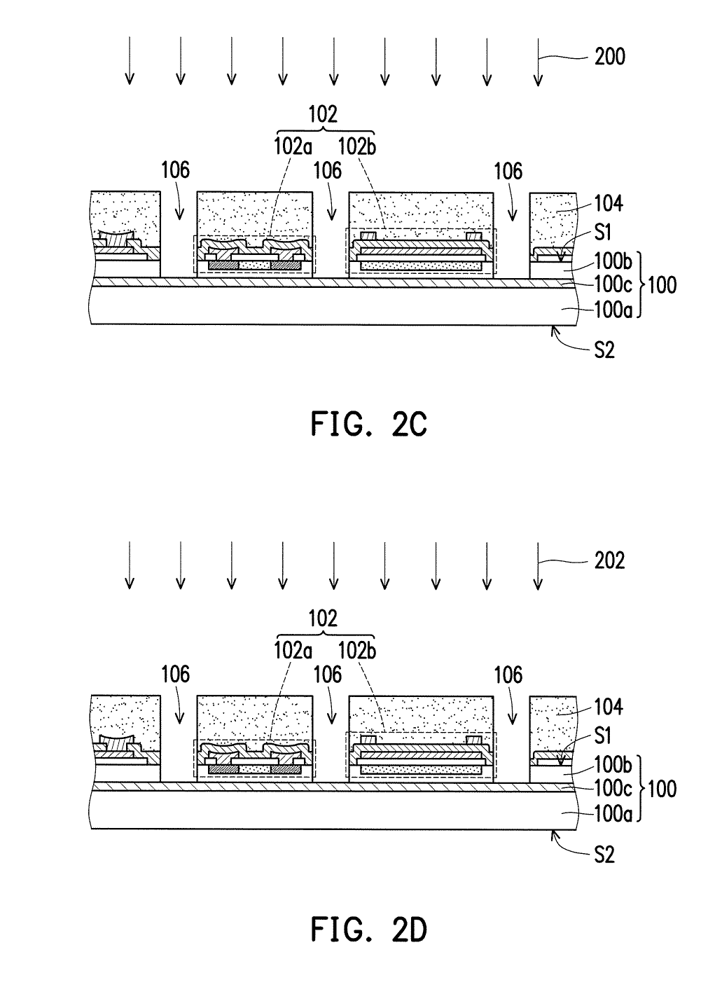

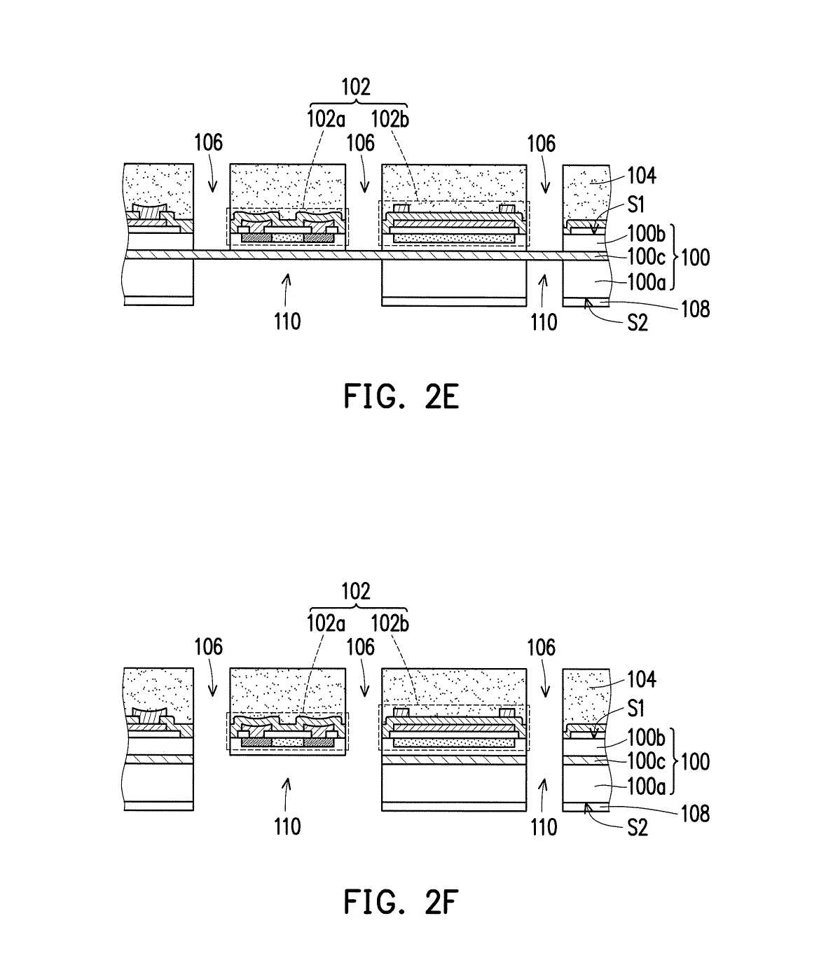

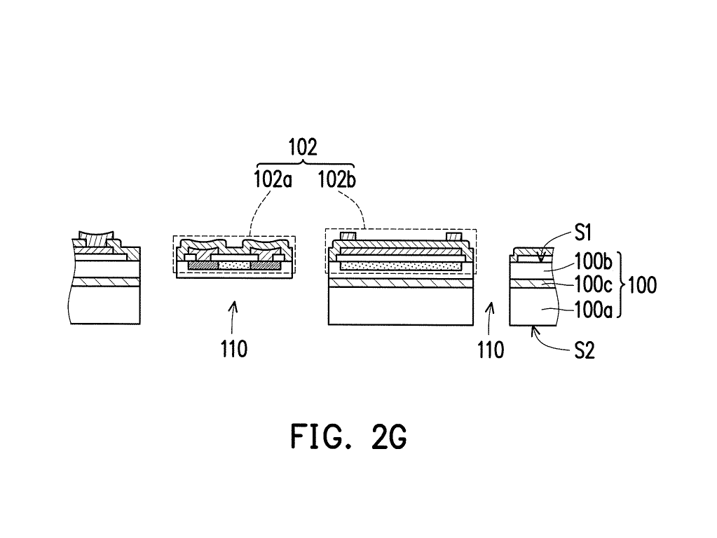

FIG. 1 is a flowchart of a semiconductor process according to an embodiment of the invention. FIG. 2A to FIG. 2G are cross-sectional views of the semiconductor process according to an embodiment of the invention.

Referring to FIG. 1 and FIG. 2A together, step S100 is performed in which a wafer 100 is provided, wherein the wafer 100 has a front side S1 and a back side S2, and the wafer 100 has a semiconductor device 102 on the front side S1. The wafer 100 may be a semiconductor wafer or a silicon-on-insulator (SOI) wafer. In the present embodiment, the wafer 100 is an SOI wafer for illustrative purposes. However, the invention is not limited thereto. For example, the wafer 100 includes a silicon substrate 100a, a silicon layer 100b and an insulating layer 100c, wherein the insulating layer 100c is disposed between the silicon substrate 100a and the silicon layer 100b. A material of the insulating layer 100c is, for example, silicon oxide.

The semiconductor device 102 is, for example, a microelectromechanical system (MEMS) device or a logic device. The MEMS device is, for example, a sensor device, such as an accelerometer, a MEMS microphone, a photosensor or a gas sensor. In the present embodiment, the semiconductor device 102 is an accelerometer among the MEMS devices for illustrative purposes. However, the invention is not limited thereto. For example, in cases where the semiconductor device 102 is an accelerometer, the semiconductor device 102 includes a cantilever beam 102a (cantilevered member) and a proof mass 102b.

Step S102 is optionally performed in which a thinning process is performed on the back side S2 of the wafer 100, so as to remove a portion of the wafer 100. For example, a portion of the silicon substrate 100a of the wafer 100 may be removed. The thinning process is, for example, a grinding process.

Step S104 is performed in which a protection layer 104 is formed on the front side S1 of the wafer 100, wherein the protection layer 104 covers the semiconductor device 102, and a material of the protection layer 104 includes a photoresist material. The photoresist material is, for example, an I-line photoresist, an ArF photoresist or a KrF photoresist. The I-line photoresist, the ArF photoresist and the KrF photoresist are respectively photoresist materials photosensitive to an I-line light source (having a wavelength of 365 nm), an ArF gas laser (having a wavelength of 193 nm) and a KrF gas laser (having a wavelength of 248 nm).

In the present embodiment, for illustrative purposes, the thinning process is performed on the back side S2 of the wafer 100 (step S102) before the protection layer 104 is formed (step S104). However, the invention is not limited thereto. In another embodiment, the thinning process may be performed on the back side S2 of the wafer 100 after the protection layer 104 is formed. That is, step S104 (forming the protection layer 104) may be performed first, and step S102 (thinning process) is then performed.

Referring to FIG. 1 and FIG. 2B together, step S106 is optionally performed in which a patterning process is performed on the protection layer 104. For specific process requirements, an opening 106 may be formed in the protection layer 104 by the patterning process. The patterning process is, for example, a lithography process. In other embodiments, step S106 may also be omitted.

Referring to FIG. 1, FIG. 2C and FIG. 2D together, step S108 is performed in which a surface hardening treatment process is performed on the protection layer 104, so that a surface of the protection layer 104 is hardened and better protection is thus provided.

The surface hardening treatment process in step S108 includes step S108b (ion implantation process). In addition, before step S108b is performed, the surface hardening treatment process in step S108 may further optionally include step S108a (anneal process).

In the present embodiment, the surface hardening treatment process in step S108 is, for example, as follows. Referring to FIG. 1 and FIG. 2C together, step S108a may be optionally performed in which an anneal process 200 is performed on the protection layer 104. The anneal process facilitates hardening of the surface of the protection layer 104. A temperature of the anneal process is, for example, 150° C. to 250° C. In an embodiment, the temperature of the anneal process is about 200° C.

Referring to FIG. 1 and FIG. 2D together, step S108b is performed in which an ion implantation process 202 is performed on the protection layer 104, so as to harden the surface of the protection layer 104. In order to impart required surface stiffness to the protection layer 104, a dopant to be implanted must match selected implantation concentration and implantation energy. For example, a dopant having great atomic weight, such as phosphorus (P), requires a greater implantation energy, while a dopant having small atomic weight, such as boron (B), requires a smaller implantation energy, so that the dopant can be distributed within a surface layer of the protection layer 104. The dopant of the ion implantation process is, for example, phosphorus, boron or arsenic. The implantation concentration of the ion implantation process is, for example, 1×10¹⁵ ions/cm² to 4×10¹⁵ ions/cm². The implantation energy of the ion implantation process is, for example, 50 keV to 100 keV. In an embodiment, the implantation concentration of the ion implantation process may be 2.25×10¹⁵ ions/cm², and the implantation energy of the ion implantation process may be 70 keV. In the present embodiment, the protection layer 104 is hardened by the ion implantation process 202 as an example, but the invention is not limited thereto. In other embodiments, the ion implantation process 202 in Step S108b can be replaced by an UV treatment or an e-beam treatment, and the protection layer 104 can be hardened by the UV treatment or the e-beam treatment.

Then, referring to FIG. 1 and FIG. 2E to FIG. 2G together, step S110 is performed in which a patterning process is performed on the back side S2 of the wafer 100, so as to form a required opening 110 on the back side S2 of the wafer 100. The opening 110 is, for example, a cavity or a through hole.

Hereinafter, the patterning process in step S110 is explained with reference to FIG. 2E to FIG. 2G.

Referring to FIG. 2E, a patterned photoresist layer 108 is formed on the back side S2 of the wafer 100. A material of the patterned photoresist layer 108 is, for example, an I-line photoresist, an ArF photoresist or a KrF photoresist. The patterned photoresist layer 108 is, for example, formed by a lithography process.

Referring to FIG. 2E and FIG. 2F together, a portion of the wafer 100 is removed from the back side S2 of the wafer 100 using the patterned photoresist layer 108 as a mask, so as to form the opening 110 in the wafer 100. A method for removing the portion of the wafer 100 is, for example, a dry etching process, a wet etching process or a combination thereof.

For example, referring to FIG. 2E, a portion of the silicon substrate 100a that is exposed by the patterned photoresist layer 108 is removed from the back side S2 of the wafer 100 by a dry etching process using the patterned photoresist layer 108 as the mask, thereby forming the opening 110. The dry etching process is, for example, a deep reactive ion etching (DRIE) process. Next, referring to FIG. 2F, the insulating layer 100c exposed by the patterned photoresist layer 108 is optionally removed. In detail, the insulating layer 100c exposed by the patterned photoresist layer 108 may be removed from the back side S2 of the wafer 100 by a wet etching process or a dry etching process, using the patterned photoresist layer 108 as the mask. At this moment, the openings 110 and 106 may communicate with each other. An etchant used in the wet etching process is, for example, hydrofluoric acid (HF) or a buffered oxide etchant (BOE).

Next, referring to FIG. 2G, the patterned photoresist layer 108 is removed. A method for removing the patterned photoresist layer 108 is, for example, dry stripping or wet stripping.

Referring to FIG. 1 and FIG. 2G together, step S112 is optionally performed in which the protection layer 104 is removed. A method for removing the protection layer 104 is, for example, dry stripping or wet stripping. The sequence of removal of the protection layer 104 and the patterned photoresist layer 108 is not fixed. In cases where the protection layer 104 and the patterned photoresist layer 108 have the same component, the protection layer 104 and the patterned photoresist layer 108 can be removed at the same time by the same removing process, thereby further reducing complexity of the process. In addition, in cases where the protection layer 104 and the patterned photoresist layer 108 have different components, the patterned photoresist layer 108 may be removed first and then the protection layer 104 may be removed, or the protection layer 104 may be removed first and then the patterned photoresist layer 108 may be removed.

Based on the above embodiment, since the protection layer 104 is subjected to the surface hardening treatment process, when the patterning process is performed on the back side S2 of the wafer 100, the surface hardening-treated protection layer 104 can effectively protect the front side S1 of the wafer 100. Therefore, whether the patterning process performed on the back side S2 of the wafer 100 is a dry etching process or a wet etching process, by the protection layer 104, the semiconductor device 102 on the front side S1 of the wafer 100 can be prevented from being damaged, and reliability and yield of the semiconductor device 102 can be further improved.

In summary, in the semiconductor process of the above embodiment, during a backside process, the front side of the wafer can be effectively protected by the surface hardening-treated protection layer, and reliability and yield of the semiconductor device can be further improved.

Although the invention has been described with reference to the above embodiments, it will be apparent to one of ordinary skill in the art that modifications to the described embodiments may be made without departing from the spirit of the invention. Accordingly, the scope of the invention will be defined by the attached claims and not by the above detailed descriptions.

What is claimed is:

1. A semiconductor process, comprising:
providing a wafer, wherein the wafer has a front side and a back side, and the wafer has a semiconductor device on the front side;
forming a protection layer on the front side of the wafer, wherein the protection layer covers the semiconductor device, and a material of the protection layer comprises a photoresist material;
performing a surface hardening treatment process on the protection layer; and
performing a first patterning process on the back side of the wafer.

2. The semiconductor process according to claim 1, wherein the semiconductor device comprises a microelectromechanical system (MEMS) device or a logic device.

3. The semiconductor process according to claim 2, wherein the MEMS device comprises a sensor device.

4. The semiconductor process according to claim 3, wherein the sensor device comprises an accelerometer, a MEMS microphone, a photosensor or a gas sensor.

5. The semiconductor process according to claim 1, further comprising, before or after forming the protection layer, performing a thinning process on the back side of the wafer.

6. The semiconductor process according to claim 5, wherein the thinning process comprises a grinding process.

7. The semiconductor process according to claim 1, wherein the photoresist material comprises an I-line photoresist, an ArF photoresist or a KrF photoresist.

8. The semiconductor process according to claim 1, further comprising, before performing the surface hardening treatment process, performing a second patterning process on the protection layer.

9. The semiconductor process according to claim 8, wherein the second patterning process comprises a lithography process.

10. The semiconductor process according to claim 1, wherein the surface hardening treatment process comprises performing an ion implantation process, an UV treatment or an e-beam treatment on the protection layer.

11. The semiconductor process according to claim 10, wherein a dopant of the ion implantation process comprises phosphorus, boron or arsenic.

12. The semiconductor process according to claim 10, wherein an implantation concentration of the ion implantation process is 1×10¹⁵ ions/cm² to 4×10¹⁵ ions/cm².

13. The semiconductor process according to claim 10, wherein an implantation energy of the ion implantation process is 50 keV to 100 keV.

14. The semiconductor process according to claim 10, further comprising, before performing the ion implantation process, performing an anneal process on the protection layer.

15. The semiconductor process according to claim 14, wherein a temperature of the anneal process is 150° C. to 250° C.

16. The semiconductor process according to claim 1, wherein the first patterning process comprises:
forming a patterned photoresist layer on the back side of the wafer; and
removing a portion of the wafer from the back side of the wafer using the patterned photoresist layer as a mask.

17. The semiconductor process according to claim 16, wherein a method for removing the portion of the wafer comprises a dry etching process, a wet etching process or a combination thereof.

18. The semiconductor process according to claim 17, wherein the dry etching process comprises a deep reactive ion etching (DRIE) process.

19. The semiconductor process according to claim 16, further comprising, after removing the portion of the wafer, removing the patterned photoresist layer.

20. The semiconductor process according to claim 1, further comprising, after performing the first patterning process, removing the protection layer.
